(19) United States
(12) Patent Application Publication
(10) Pub. No.: US 2017/0329190 A1
(43) Pub. Date: Nov. 16, 2017

(54) ARRAY SUBSTRATE AND MANUFACTURING METHOD FOR THE SAME, AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Lindong CHEN, Beijing (CN); Hongwei XUE, Beijing (CN); Qiao JIANG, Beijing (CN); Junhao LIU, Beijing (CN)

(21) Appl. No.: 15/519,959

(22) PCT Filed: Jan. 13, 2016
(86) PCT No.: PCT/CN2016/070767

§ 371 Date: Apr. 18, 2017

(30) Foreign Application Priority Data
Aug. 18, 2015 (CN) 201510509180.0

(51) Int. Cl. G02F 1/1362; G02F 1/1333; H01L 27/12

(52) U.S. Cl. CPC G02F 1/136286; H01L 27/1262; H01L 27/124; G02F 1/133345; G02F 2001/13629; G02F 2001/136295

(57) ABSTRACT

Embodiments of the present disclosure provide an array substrate and a manufacturing method for the same, and a display device. The array substrate includes a display region, and a package region arranged around the display region. The package region includes a plurality of separated signal line regions. In at least one of the signal line regions, at least two signal lines which are insulated from and overlapped with each other are arranged. In embodiments of the present disclosure, the coverage area of the signal lines on the package region may be effectively reduced as compared with the conventional structure in which the signal lines are arranged in one circuit layer. Therefore, the influence of the signal lines on the package region on the curing effect may be effectively reduced when the UV light is irradiated from the array substrate side for UV curing.

### CROSS REFERENCE TO RELATED APPLICATIONS

This application is a National Stage Entry of PCT/CN2016/070767 filed Jan. 13, 2016, which claims the benefit and priority of Chinese Patent Application No. 201510509180.0, filed on Aug. 18, 2015, the disclosures of which are incorporated by reference herein in their entity as part of the present application.

### BACKGROUND

The present disclosure relates to the field of display technology, and particularly, to an array substrate and a manufacturing method for the same, and a display device.

Liquid Crystal Display (LCD) has the advantages of high display quality, low power consumption and no radiation. It has been developed rapidly in recent years and has been widely used in various fields.

The conventional liquid crystal display panel mainly includes an array substrate, a color film substrate, and a liquid crystal layer. In the conventional liquid crystal display panel manufacturing process, firstly the sealant is coated between the array substrate and the color film substrate, then the array substrate and the color film substrate are combined and the liquid crystal layer is sealed between the two substrates in a cell process, and finally the required liquid crystal display panel is formed through the sealant curing process. The existing sealant curing methods include ultraviolet (UV) curing utilizing ultraviolet (UV) light irradiation and heat curing utilizing thermal energy, wherein the UV curing has more obvious curing effect on the sealant. For recently common miniaturized products with high resolution, if the UV light is irradiated from the color film substrate side during the UV curing process, the sealant is blocked by a Black Matrix (BM) on the color film substrate, and a poor curing is likely to be caused. Therefore, the UV light is usually irradiated from the array substrate side. However, an opaque signal line is often formed on the package region of the array substrate, wherein the package region is for coating the sealant. The opaque signal line also affects the transmittance of the UV light more or less, thereby affecting the curing effect.

### BRIEF DESCRIPTION

The array substrate and the manufacturing method for the same, and the display device provided by embodiments of the present disclosure can reduce the influence of signal lines on the package region of the array substrate to the UV curing effect.

According to a first aspect, embodiments of the present disclosure provide an array substrate including a display region, and a package region arranged around the display region, wherein the package region includes a plurality of separated signal line regions, and at least two signal lines are arranged in at least one of the signal line regions, to be insulated from and overlapped with each other.

In embodiments of the present disclosure, signal lines in the plurality of signal line regions are extended in the same direction.

In embodiments of the present disclosure, in the signal line regions, a projection, on the array substrate, of one of the at least two signal lines covers a projection, on the array substrate, of another one of the at least two signal lines.

In embodiments of the present disclosure, in the signal line regions, the at least two signal lines have the same width.

In embodiments of the present disclosure, the number of signal lines is the same in each of the signal line regions.

In embodiments of the present disclosure, the signal line includes a main portion, a first extension portion at one end, and a second extension portion at the other end. The first extension portions of the signal lines in the signal line regions are arranged on the same layer and do not overlap with each other. The second extension portions of the signal lines in the signal line regions are arranged on the same layer and do not overlap with each other.

In embodiments of the present disclosure, the first extension portions of the signal lines are parallel to each other, and the second extension portions of the signal lines are parallel to each other.

In embodiments of the present disclosure, in the signal line regions, first extension portions of at least two signal lines are arranged next to each other, and second extension portions are arranged next to each other.

In embodiments of the present disclosure, an insulating layer is arranged between at least two signal lines in the signal line regions.

According to a second aspect of the present disclosure, embodiments of the present disclosure provide a display device including the above-described array substrate.

According to a third aspect of the present disclosure, embodiments of the present disclosure provide a manufacturing method for an array substrate including forming a display region, forming a package region around the display region, forming a plurality of separated signal line regions in the package region, and forming at least two signal lines which are insulated from and overlapped with each other in at least one of the signal line regions.

In embodiments of the present disclosure, the signal lines in the signal line regions are extended in the same direction.

In embodiments of the present disclosure, in the signal line regions, a projection, on the array substrate, of one of the at least two signal lines covers a projection, on the array substrate, of another one of the at least two signal lines.

In embodiments of the present disclosure, in the signal line regions, the at least two signal lines have the same width.

In embodiments of the present disclosure, the number of signal lines is the same in each of the signal line regions.

In embodiments of the present disclosure, the signal line includes a main portion, a first extension portion at one end, and a second extension portion at the other end. The first extension portions of the signal lines in the signal line regions are arranged on the same layer and do not overlap with each other. The second extension portions of the signal lines in the signal line regions are arranged on the same layer and do not overlap with each other.

In embodiments of the present disclosure, the first extension portions of the signal lines are parallel to each other and the second extension portions of the signal lines are parallel to each other.

In embodiments of the present disclosure, in the signal line regions, first extension portions of at least two signal lines are arranged next to each other and second extension portions are arranged next to each other.

In embodiments of the present disclosure, an insulating layer is arranged between at least two signal lines in the signal line regions.

According to embodiments of the present disclosure, the signal lines on the package region of the array substrate are arranged in a plurality of circuit layers, and the projections, on the array substrate, of signal lines respectively located in different layers of the plurality of circuit layers overlap with each other. Compared with the conventional structure in which the signal lines are arranged in one circuit layer, the coverage area, on the package region, of the signal lines may be effectively reduced. Therefore, when the UV light is irradiated from the array substrate side for UV curing, the influence of the signal lines on the package region on the curing effect may be effectively reduced.

### BRIEF DESCRIPTION OF THE DRAWINGS

In order to more clearly illustrate the technical solution of embodiments of the present disclosure, the drawings of the embodiments will be briefly described below. It should be understood that the drawings described below merely relate to some embodiments of the disclosure and are not intended to be limiting of the disclosure, in which:

FIG. 1 is a schematic structural view of an array substrate provided in a first embodiment of the present disclosure;

FIG. 2 is a schematic cross-sectional view of the array substrate of the embodiment shown in FIG. 1 in the direction of AA′ in FIG. 1;

FIG. 3 is a schematic structural view of an array substrate provided in a second embodiment of the present disclosure; and

FIG. 4 is a schematic structural view of an array substrate provided in a third embodiment of the present disclosure.

### DETAILED DESCRIPTION

To make the technical solutions and advantages of the embodiments of the present disclosure more apparent, the technical solutions in the embodiments of the present disclosure are clearly and completely described below in conjunction with the accompanying drawings in the embodiments of the present disclosure. Apparently, the embodiments described are merely a part of the present disclosure, rather than all of the embodiments. All other embodiments obtained by those of ordinary skill in the art based on embodiments of the disclosure without making creative work are within the scope of protection of the present disclosure.

FIG. 1 is a schematic structural view of an array substrate provided in a first embodiment of the present disclosure. According to a first embodiment of the present disclosure, there is provided an array substrate including a display region, and a package region arranged around the display region. The package region includes a plurality of separated signal line regions. At least two signal lines are arranged in at least one of the signal line regions, to be insulated from and overlapped with each other. In this embodiment, the signal lines in the plurality of signal line regions may be extended in the same direction. In this embodiment, in the signal line regions, the at least two signal lines may have the same width.

In the signal line regions, there may be at least two layers of circuit layers corresponding to the at least two signal lines. Each one of the at least two layers of circuit layers includes one signal line. Also, for example, when the circuit layer is formed by a printing technique, in the different signal line regions, the circuit layers in the same layer and the signal lines in these circuit layers can be simultaneously formed.

That is, in the perspective for circuit layers, a plurality of signal lines in the package region are insulated from each other and divided into a plurality of groups, each of which is arranged in the same circuit layer.

According to the array substrate of the present embodiment, the signal lines on the package region of the array substrate are arranged in a plurality of signal line regions with a multilayer structure, and at least two signal lines in the signal line regions overlap with each other. Compared with the conventional structure in which the signal lines are arranged in one circuit layer without a overlapped structure, the coverage area, on the package region, of the signal lines may be effectively reduced. Therefore, when the UV light is irradiated from the array substrate side for UV curing, the influence of the signal lines on the package region on the curing effect may be effectively reduced.

In this example, the plurality of signal lines on the package region of the array substrate may be extended in the same direction, and in each circuit layer, a plurality of signal lines may be arranged with an equal interval. With the signal lines overlapping with each other, the area of the light transmission region on the package region may be effectively improved.

In addition, in order to better insulate adjacent signal lines, a transparent insulating layer may be arranged between adjacent signal lines.

In addition, the width of the signal lines, the number of the signal lines in the signal line regions and the positions thereof may be designed appropriately, such that in the signal line regions abovementioned, there is a signal line, whose projection on the array substrate completely covers the projections of other signal lines on the array substrate. Thus, when UV curing is performed, in the signal line regions, the irradiated UV light is blocked only in the region covered by this signal line.

Referring to FIG. 1, the array substrate includes a display region, and a package region arranged around the display region. The package region of the array substrate includes two layers of circuit layers which are superimposed. A plurality of signal lines extended in the same direction are arranged in the two layers of circuit layers. The plurality of signal lines are divided into two groups. One group of signal lines includes a plurality of signal lines 111 arranged with equal intervals located on the first layer of circuit layer, and the plurality of signal lines 111 respectively belong to a plurality of separated signal line regions. The other group of signal lines includes a plurality of signal lines 131 arranged with equal intervals located on the second layer of circuit layer, and the plurality of signal lines 131 respectively belong to a plurality of separated signal line regions.

As shown in FIG. 1, taking one signal line region as an example, since the signal lines 111 in the first layer of circuit layer are arranged corresponding to the signal lines 131 in the second layer of circuit layer, and the width of the signal line 131 is smaller than that of the signal line 111, on the package region, the projection of the signal lines 131 in the second layer of circuit layer on the array substrate is completely within the projection of the signal lines 111 in the first layer of circuit layer on the array substrate. Therefore, when the UV light is irradiated, the blocking of the UV light by the signal lines 131 in the second layer of circuit layer is avoided. Compared with the conventional structure having only one layer of circuit layer, the transmittance of the UV light may be greatly improved, thereby improving the curing effect.

In the array substrate of the present embodiment, the signal line includes a main portion, a first extension portion at one end extending toward the edge direction of the array substrate, and a second extension portion at the other end extending toward the display region direction. Through a first extension portion of the signal line, a signal line may be connected to other peripheral circuits on the array substrate, such as a Gate Drive on Array (GOA) unit, a Bonding Pad structure, or the like. Through a second extension line, the signal line may be connected to a circuit within the display region of the array substrate, such as to a gate line, a data line, or the like.

The first extension portions of the signal lines in the signal line regions are arranged on the same layer and do not overlap with each other, and the second extension portions of the signal lines in the signal line regions are arranged on the same layer and do not overlap with each other. The first extension portions of the signal lines are parallel to each other and the second extension portions of the signal lines are parallel to each other. In the signal line regions, the first extension portions of the signal lines are arranged next to each other and the second extension portions are arranged next to each other.

As shown in FIG. 1, the signal line 111 in the first layer of circuit layer includes a first extension portion 112 extending toward the edge direction of the array substrate and a second extension portion 113 extending toward the display region direction. The signal line 131 in the second layer of circuit layer includes a first extension portion 132 extending toward the edge direction of the array substrate and a second extension portion 133 extending toward the display region direction. For the above-described two-layer circuit layer structure, when a printing technique is employed, a plurality of signal lines 111 of the first layer of circuit layers with their extension portions (comprising the first extension portion 112 and the second extension portion 113) may be formed first, then the insulating layer 120 is formed, and a plurality of signal lines 131 of the second layer of circuit layers with their extension portions (including the first extension portion 132 and the second extension portion 133) are finally manufactured.

In the array substrate of this embodiment, in order to further increase the area of the light transmission region on the package region, the width of the signal lines may be reduced as far as possible without affecting the signal transmission performance of the signal lines. The width of each signal line on the package region and the number of signal lines included in the signal line regions may be the same, such that the number of signal lines in different circuit layers is also the same. In this way, the signal lines may be sparser effectively. For the conventional array substrate, if the ratio of the light transmission region on the package region is a and the coverage of the signal lines is 1−α, then for the array substrate of the present embodiment, if the signal lines are arranged as for example n layers of circuit layers, the ratio of the light transmission region thereof can be increased to: α+(1−1/n)(1−α).

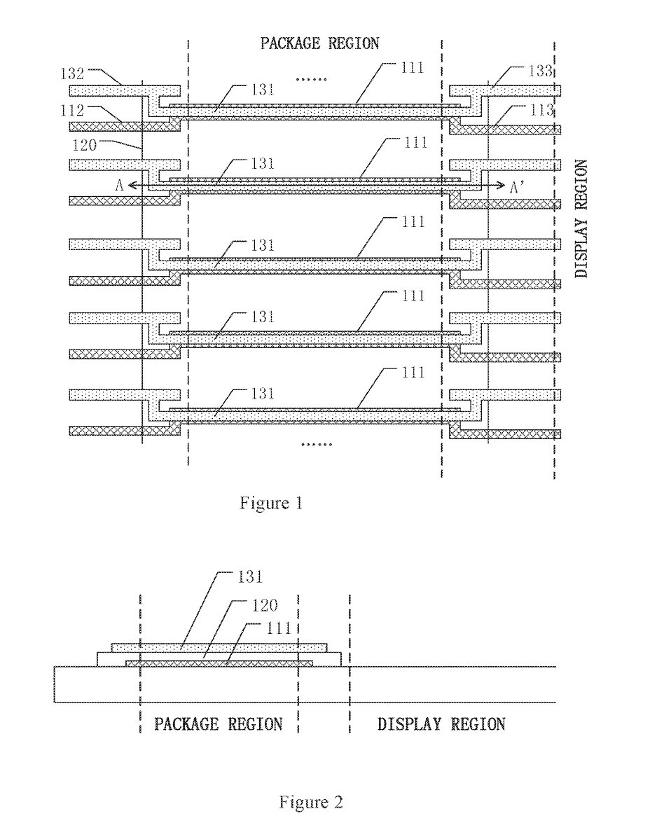

FIG. 2 is a schematic cross-sectional view of the array substrate of the embodiment shown in FIG. 1 in the direction of AA′ in FIG. 1. As shown in FIG. 2, the signal lines 111 and the signal lines 131 in the two layers of circuit layer are superimposed and separated from each other by the transparent insulating layer 120.

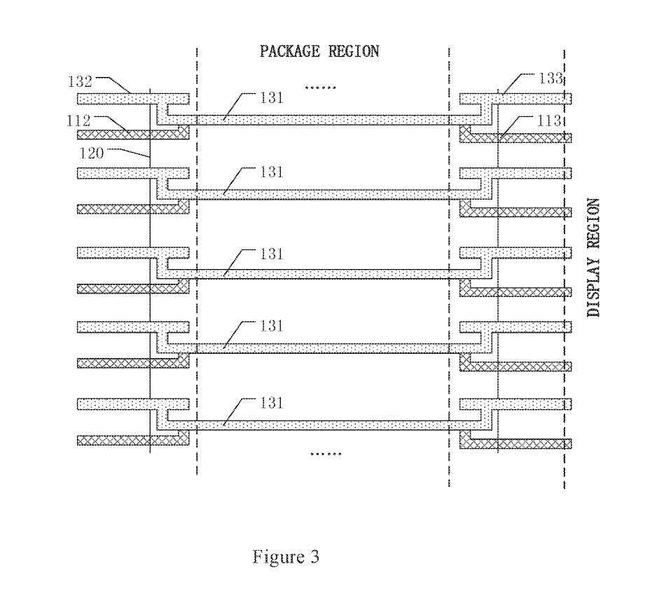

FIG. 3 is a schematic structural view of an array substrate provided in a second embodiment of the present disclosure. As shown in FIG. 3, the package region of the array substrate includes two layers of circuit layers, the first layer of circuit layer includes a plurality of signal lines 111 extended in the same direction, and the second layer of circuit layer includes a plurality of signal lines 131 extended in the same direction. In the two layers of circuit layer, the width, extension direction, number and position of the signal lines are the same. The light transmission area of the package region may be further increased. The transmittance of UV light during the UV curing may be improved, and the curing effect may be improved.

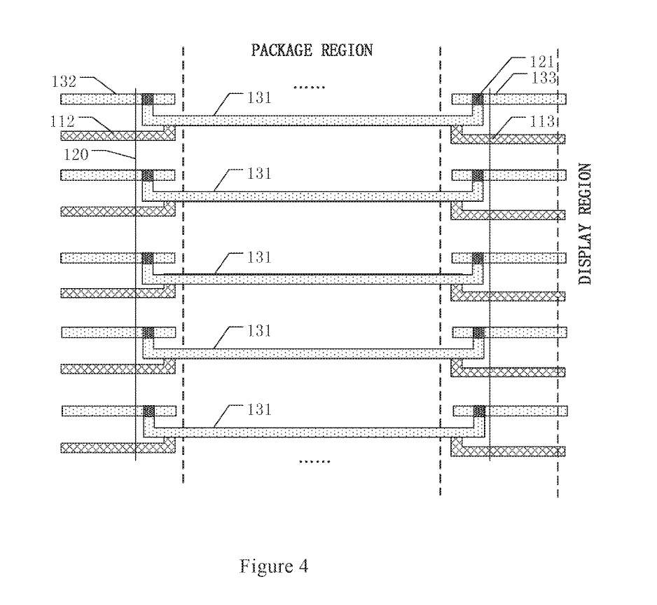

FIG. 4 is a schematic structural view of an array substrate provided in a third embodiment of the present disclosure. In embodiments of the present disclosure, the extension portions of all the signal lines on the package region may be manufactured in the same circuit layer by a one patterning process.

Referring to FIG. 4, the package region of the array substrate includes two layers of circuit layer, the first layer of circuit layer including a plurality of signal lines 111 extended in the same direction, and the second layer of circuit layer including a plurality of signal lines 131 extended in the same direction. In the two layers of circuit layer, the width, extension direction, number and position of the signal lines are the same. In the above-mentioned two layers of circuit layer, the first extension portions of all the signal lines are arranged parallel to each other and on the same layer, the second extension portions of all the signal lines are arranged parallel to each other and on the same layer. For any two signal lines which are respectively located on one layer of the two layers of circuit layer and whose projections overlap with each other, the first extension portions of the both are arranged next to each other, and the second extension portions of the both are arranged next to each other. That is, the first extension portion 112 of the signal line 111 in the first layer of circuit layer is alternately arranged with the first extension portion 132 of the signal line 131 in the second layer of circuit layer, and the second extension portion 113 of the signal line 111 in the first layer of circuit layer is alternately arranged with the second extension portion 133 of the signal line 131 in the second layer of circuit layer. For the signal line 131, its first extension portion and second extension may extend through the via 121 on the insulating layer 120 to the first layer of circuit layer.

For the above-described two-layer circuit layer structure, firstly the signal lines 111 of the first layer of circuit layer with their extension portions (including the first extension portion 112 and the second extension portion 113) as well as the extension portions of the signal lines 131 of the second circuit layer (including the first extension portion 132 and the second extension portion 133) may be formed by a first patterning process, then the insulating layer 120 is formed, then the signal lines 131 of the second circuit layer may be formed by the second patterning process, and the signal lines 131 are manufactured to be connected to the extension portions thereof through the via 121 on the insulating layer 120.

According to a fourth embodiment of the present disclosure, there is provided a display device including the above-described array substrate. The display device may be any product or component having a display function, such as a notebook computer display, a liquid crystal display, an LCD TV, a digital photo frame, a mobile phone, a tablet computer, or the like.

According to a fifth embodiment of the present disclosure, there is provided a manufacturing method for an array substrate, including forming a display region, forming a package region around the display region, forming a plurality of separated signal line regions in the package region, and forming at least two signal lines which are insulated from and overlapped with each other in at least one of the signal line regions. In the signal line regions, there may be at least two circuit layers corresponding to the at least two signal lines, and each of the at least two circuit layers comprises one signal line. Also, for example, when the circuit layer is formed by a printing technique, in the different signal line regions, the circuit layers in the same layer and the signal lines in these circuit layers can be simultaneously formed. That is, in the perspective for circuit layers, a plurality of signal lines in the package region are insulated from each other and divided into a plurality of groups, each of which is arranged in one circuit layer.

In embodiments of the present disclosure, the signal lines in the signal line regions are extended in the same direction.

In embodiments of the present disclosure, in the perspective for the circuit layer, the plurality of signal lines in the package region are manufactured in different circuit layers, and each layer of circuit layers includes a plurality of signal lines arranged with equal intervals. By superimposing the plurality of layers of circuit layer formed, the area of the light transmission region of the package region may be effectively improved.

In the embodiment of the present disclosure, the widths of the signal lines, the number and position of the signal lines in each circuit layer are appropriately designed, so as to form one signal line in the above-formed signal line regions, such that the projection, on the array substrate, of this signal line covers the projections, on the array substrate, of the other of the at least two signal lines. Therefore, when the UV curing is performed, in the signal line regions, the irradiated UV light is blocked only in the region covered by this signal line.

In embodiments of the present disclosure, in order to further increase the light transmission region on the package region, in the signal line regions, the at least two signal lines have the same width and the signal line regions include the same number of signal lines.

In embodiments of the present disclosure, the signal line includes a main portion, a first extension portion at one end, and a second extension portion at the other end. The first extension portions of the signal lines in the signal line regions are arranged on the same layer and do not overlap with each other. The second extension portions of the signal lines in the signal line regions are arranged on the same layer and do not overlap with each other.

In embodiments of the present disclosure, the first extension portions of the signal lines are parallel to each other, and the second extension portions of the signal lines are parallel to each other.

In embodiments of the present disclosure, in the signal line regions, the first extension portions of the at least two signal lines are arranged next to each other, and the second extension portions of the at least two signal lines are arranged next to each other.

In embodiments of the present disclosure, in the perspective for the circuit layers, the number of the plurality of the circuit layers formed on the package region of the array substrate is two, and for two signal lines which are respectively located on one of the two layers of circuit layer and whose projections on the array substrate overlap with each other, the first extension portions are arranged next to each other, and the second extension portions are arranged next to each other.

In embodiments of the present disclosure, a transparent insulating layer is arranged between at least two signal lines in the signal line regions for insulating the adjacent two layers of circuit layer.

The above embodiments are merely illustrative of the present disclosure and are not intended to be limiting of the present disclosure, and various changes and modifications may be made by those skilled in the art without departing from the spirit and scope of the disclosure. Therefore, all equivalent technical solutions also fall within the scope of the disclosure, and the scope of patent protection of the disclosure is subject to the claims.

1. An array substrate comprising:
a display region; and
a package region arranged around the display region, wherein the package region comprises a plurality of separated signal line regions, and wherein at least two signal lines are arranged in at least one of the signal line regions, such that the at least two signal lines are insulated from and overlapped with each other.

2. The array substrate according to claim 1, wherein signal lines in the signal line regions extend in the same direction.

3. The array substrate according to claim 2, wherein in the signal line regions, a first projection, on the array substrate, of one of the at least two signal lines covers a second projection, on the array substrate, of another one of the at least two signal lines.

4. The array substrate according to claim 3, wherein in the signal line regions, the at least two signal lines have the same width.

5. The array substrate according to claim 3, wherein a number of signal lines is the same in each of the signal line regions.

6. The array substrate according to claim 2, wherein the signal lines each comprise a main portion, a first extension portion at a first end, and a second extension portion at a second end, wherein the first extension portions of the signal lines in the signal line regions are arranged on the same layer and do not overlap with each other, and wherein the second extension portions of the signal lines in the signal line regions are arranged on the same layer and do not overlap with each other.

7. The array substrate according to claim 6, wherein the first extension portions of the signal lines are parallel to each other, and wherein the second extension portions of the signal lines are parallel to each other.

8. The array substrate according to claim 6, wherein in the signal line regions, the first extension portions of the at least two signal lines are arranged next to each other, and wherein the second extension portions of the at least two signal lines are arranged next to each other.

9. The array substrate according to claim 1, wherein an insulating layer is arranged between the at least two signal lines in the signal line regions.

10. A display device comprising the array substrate according to claim 1.

11. A manufacturing method for an array substrate comprising:
forming a display region;
forming a package region around the display region;
forming a plurality of separated signal line regions in the package region; and
forming at least two signal lines which are insulated from and overlapped with each other in at least one of the signal line regions.

12. The manufacturing method for an array substrate according to claim 11, wherein signal lines in the signal line regions extend in the same direction.

13. The manufacturing method for an array substrate according to claim 12, wherein in the signal line regions, a first projection, on the array substrate, of one of the at least two signal lines covers a second projection, on the array substrate, of another one of the at least two signal lines.

14. The manufacturing method for an array substrate according to claim 13, wherein in the signal line regions, the at least two signal lines have the same width.

15. The manufacturing method for an array substrate according to claim 13, wherein a number of signal lines is the same in each of the signal line regions.

16. The manufacturing method for an array substrate according to claim 12, wherein the signal lines each comprise a main portion, a first extension portion at a first end, and a second extension portion at a second end, wherein the first extension portions of the signal lines in the signal line regions are arranged on the same layer and do not overlap with each other, and wherein the second extension portions of the signal lines in the signal line regions are arranged on the same layer and do not overlap with each other.

17. The manufacturing method for an array substrate according to claim 16, wherein the first extension portions of the signal lines are parallel to each other, and wherein the second extension portions of the signal lines are parallel to each other.

18. The manufacturing method for an array substrate according to claim 16, wherein in the signal line regions, the first extension portions of the at least two signal lines are arranged next to each other, and wherein the second extension portions are arranged next to each other.

19. The manufacturing method for an array substrate according to claim 11, wherein an insulating layer is arranged between the at least two signal lines in the signal line regions.

20. The array substrate according to claim 9, wherein in the signal line regions, a first projection, on the array substrate, of one of the at least two signal lines covers a second projection, on the array substrate, of another one of the at least two signal lines.
